(19) United States
(12) Patent Application Publication
(10) Pub. No.: US 2026/0262529 A1
(43) Pub. Date: Sep. 3, 2026

(54) METHOD OF MANUFACTURING SEMICONDUCTOR DEVICES, CORRESPONDING SUBSTRATE AND SEMICONDUCTOR DEVICE

(71) Applicant: STMicroelectronics International N.V., Geneva (CH)

(72) Inventors: Mauro MAZZOLA, Calvenzano (Bergamo) (IT); Matteo DE SANTA, Mezzago, Lombardia (MB) (IT)

(73) Assignee: STMicroelectronics International N.V., Geneva (CH)

(21) Appl. No.: 19/550,427

(22) Filed: Feb. 26, 2026

(30) Foreign Application Priority Data
Feb. 28, 2025 (IT) 102025000004128

(51) Int. Cl. H10W 72/30; H10W 70/68; H10W 72/00; H10W 90/00

(52) U.S. Cl. CPC H10W 72/381; H10W 70/682; H10W 72/07302; H10W 72/07332; H10W 72/342; H10W 90/734

(57) ABSTRACT

A semiconductor die has a die-attachment surface in contact with die-attach material provided at a die mounting region of a surface of a substrate. Die-attach material is provided at a first portion of at least one recess formed in the surface of the substrate. The first portion of the at least one recess lies within the mounting region and the at least one recess includes second portions lying adjacent the mounting region. The second portions of at least one recess facilitate accumulation of die-attach material oozing out of the first portion of at least one recess in response to the semiconductor die being arranged onto the die-attach material provided at the mounting region.

### PRIORITY CLAIM

This application claims the priority benefit of Italian Application for Patent No. 102025000004128 filed on Feb. 28, 2025, the content of which is hereby incorporated by reference in its entirety to the maximum extent allowable by law.

### TECHNICAL FIELD

The description relates to semiconductor devices.

One or more embodiments can be applied to integrated circuit (IC) semiconductor devices for automotive applications, for instance.

### BACKGROUND

Current manufacturing processes of (integrated circuit, IC) semiconductor devices may involve attaching a semiconductor die on a substrate such as a leadframe, for instance. The semiconductor die may be attached at the leadframe via die-attach material provided at a mounting surface of the leadframe.

In such semiconductor devices, reliability issues may arise from relatively poor adhesion of the semiconductor die to the die-attach material; in worst cases, the semiconductor die may detach from the die-attach material, causing failure or rejection of the semiconductor device.

Moreover, semiconductor dice may bend or deform. In such cases, reliability of the die-attachment may be negatively affected by the curved surface of the semiconductor die that is intended to mount onto the substrate.

There is a need in the art to overcome the drawbacks discussed in the foregoing.

### SUMMARY

One or more embodiments relate to a method.

One or more embodiments relate to a substrate for use in such a method.

One or more embodiments relate to a corresponding (integrated circuit) semiconductor device.

Solutions as described herein involve mounting a semiconductor die on a substrate having at least one recess formed in a surface thereof.

In solutions as described herein, pillar-like formations may be provided at a surface of a semiconductor die configured to contact die-attach material provided at a surface of a substrate.

In solutions as described herein, the semiconductor die having at a surface the pillar-like formations is arranged on a substrate having one or more recesses formed at the surface thereof, with the pillar-like formations housed in the recess.

In solutions as described herein, the one or more recesses in the surface of the substrate may be at least partially filled with die-attach material.

In solutions as described herein, the pillar-like formations at the surface of the semiconductor die are dipped into the die-attach material partially filling the one or more recesses in the surface of the substrate. Interlocking between the pillar-like formations and the die-attach material counters delamination of the semiconductor die from the die-attach material.

Solutions as described herein may advantageously be applied to semiconductor die having a warped or deformed shape.

### BRIEF DESCRIPTION OF THE DRAWINGS

One or more embodiments will now be described, by way of example only, with reference to the annexed figures, wherein:

FIGS. 1 and 2 are respectively a plan view and a cross-sectional view (along line II-II of FIG. 1) illustrative of a semiconductor die arranged on a substrate;

FIGS. 3A to 3C are cross-sectional views illustrative of processing steps to arrange a semiconductor die onto a substrate;

FIG. 4 is a plan view illustrative of possible issues that may arise from processing steps as illustrated in FIGS. 3A to 3C;

FIGS. 5A to 5C are cross-sectional views illustrative of processing steps to arrange a semiconductor die onto a substrate;

FIG. 6 is a plan view illustrative of possible issues that may arise from processing steps as illustrated in FIGS. 5A to 5C;

FIGS. 7 and 8 are respectively a plan view and a cross-sectional view (along line VIII-VIII of FIG. 7) illustrative of a substrate;

FIGS. 9 and 10 are cross-sectional views (wherein FIG. 10 is an enlarged view of the portion of FIG. 9 indicated by the arrow X) illustrative of a semiconductor die that is configured to be mounted on a substrate as exemplified in FIGS. 7 and 8;

FIGS. 11A to 13A and 11B to 13B are sequences of plan views and cross-sectional views, respectively, illustrative of processing steps;

FIGS. 14 and 15 are respectively a plan view and a cross-sectional view (along line XV-XV of FIG. 14) illustrative of a substrate;

FIG. 16 is a cross-sectional view illustrative of a semiconductor die that is configured to be mounted on a substrate as exemplified in FIGS. 14 and 15;

FIGS. 17A and 17B are cross-sectional views illustrative, respectively, of a substrate and a semiconductor die configured to be arranged thereon; and

FIGS. 18A and 18B are cross-sectional views illustrative, respectively, of a substrate and a semiconductor die configured to be arranged thereon.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

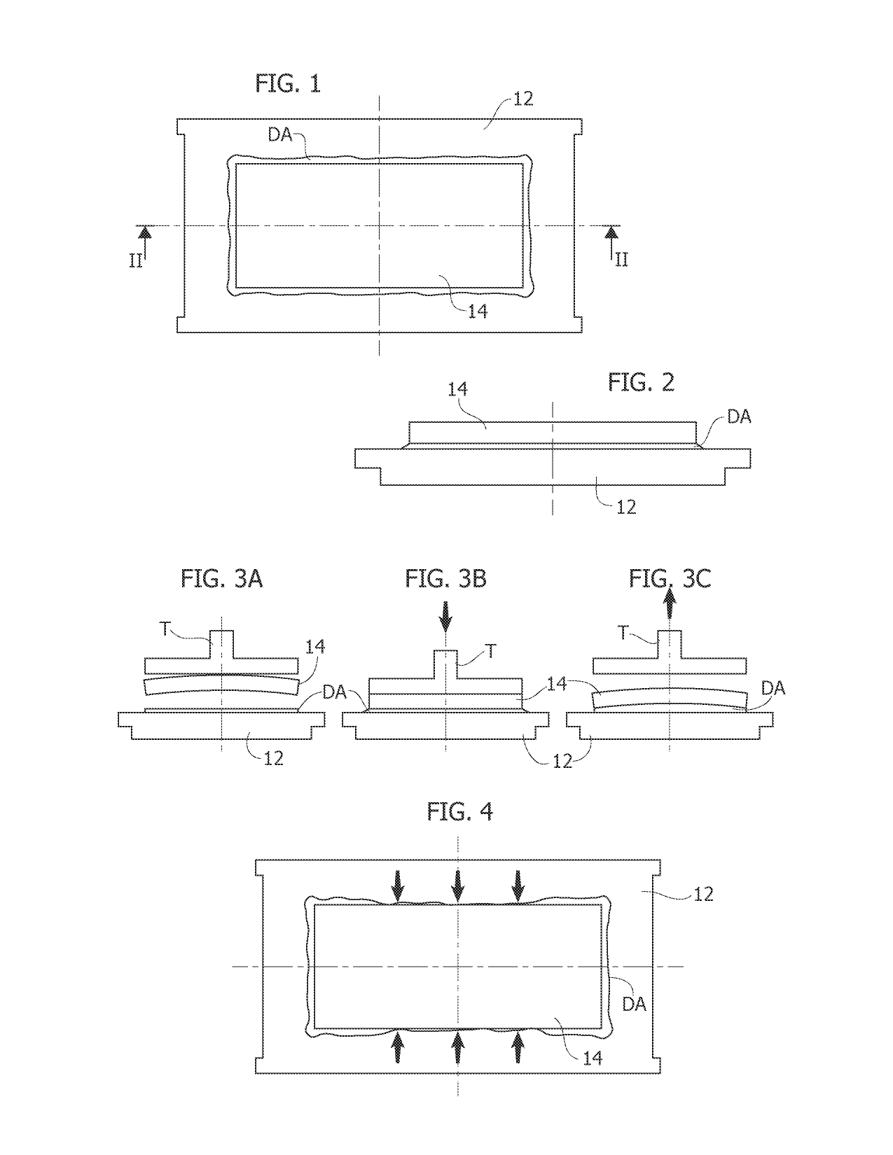

FIGS. 1 and 2 are respectively a plan view and a cross-sectional view (along line II-II of FIG. 1) illustrative of an integrated circuit semiconductor (Si, SiC or GaN, for instance) die or chip 14 arranged at a surface of a mounting substrate 12.

The substrate 12 may be, for instance a die pad in a leadframe. The designation “leadframe” (or “lead frame”) is currently used (see, for instance the USPC Consolidated Glossary of the United States Patent and Trademark Office) to indicate a metal frame that provides support for an integrated circuit chip or die (the terms chip/chips and die/dice are herein regarded as synonymous) as well as electrical leads to interconnect the integrated circuit in the die to other electrical components or contacts.

Essentially, a leadframe comprises an array of electrically-conductive formations that from an outline location extend inwardly in the direction of a semiconductor die 14 thus forming an array of electrically-conductive formations from a die pad (the substrate 12 of FIGS. 1 and 2, for instance) configured to have at least one (integrated circuit, IC) semiconductor die attached thereon.

A device as illustrated in FIGS. 1 and 2 may be further processed to obtain a finished semiconductor device. Further processing steps may comprise, for instance: providing electrical coupling (via wire bonding, for instance) between the semiconductor die 14 and the mounting substrate 12 (to the leads and/or the die pad, for instance); and molding electrically insulating molding compound (an epoxy resin, for instance) to provide a protective plastic package to the device 10.

Processing as described in the foregoing is conventional in the art, which makes it unnecessary to provide a more detailed description.

As illustrated, die-attach material DA is provided at the mounting surface (that is, the top or front surface) of the (mounting) substrate 12 in order to facilitate mounting the semiconductor die 14 thereon. The die-attach material DA may comprise, for instance, a solder paste or a die-attach glue.

A semiconductor die 14 as illustrated in the figures has die bonding pads (that is, electrical contacts) at a top or active surface thereof. With reference to FIG. 2, the semiconductor die 14 is arranged with a back or die-attachment surface opposite said active surface of the semiconductor die 14 in contact with the die-attach material DA.

FIGS. 1 and 2 are illustrative of a case where the semiconductor die 14 comprises a substantially flat body, with flat, parallel active (top) and die-attachment (bottom) surfaces. In other cases, the semiconductor die 14 may undesirably bend with undesired consequences on the die-attachment process.

FIGS. 3A to 3C are illustrative of processing steps in mounting a semiconductor die 14 on a substrate 12 in a more realistic case where the semiconductor die 14 has a certain degree of warpage or deformation.

A semiconductor die 14 may bend or warp in response to previous processing steps (processing steps such as diffusion processes or when metal volumes are provided in the semiconductor die with a non-uniform distribution, for instance); subsequently to wafer singulation, the semiconductor dice 14 are observed to warp/bend or, more generally, to deform (almost) permanently, with no simple solutions to restore a (substantially) flat shape.

Semiconductor dice 14 having a length to width ratio greater than 2 have been observed to bend more severely, for instance.

Two possible deformations of the semiconductor dice 14 are observed: a “crying” warpage, wherein the die-attachment surface of the semiconductor die 14 has a concave shape (that is, where the edges of a semiconductor die 14 bend downward when the semiconductor die 14 is arranged with the active surface facing upward); or a “smiling” warpage, wherein the die-attachment surface of the semiconductor die 14 has a convex shape (that is, where the edges of a semiconductor die 14 bend upward when the semiconductor die 14 is arranged with the active surface facing upward).

FIGS. 3A to 3C are thus illustrative of a semiconductor die 14 having a “crying” warpage being arranged on a substrate 12 via die-attach material DA provided on the substrate 12.

As illustrated in FIG. 3A, a “crying” semiconductor die 14 is arranged on a mounting surface of a substrate 12 (a die pad, for instance) via pick-and-place equipment T. The mounting surface of the substrate 12 has die-attach material DA (a solder paste or a die-attach glue, for instance) provided therein.

FIG. 3B is illustrative of the semiconductor die 14 arranged with the die-attachment (back) surface thereof in contact with the die-attach material DA. As schematically illustrated with an arrow pointing downward, the pick-and-place equipment T applies a mechanical pressure onto the semiconductor die 14 that may cause the semiconductor die 14 to flatten and adhere to the die-attach material DA.

However, as illustrated in FIG. 3C, when the semiconductor die 14 is released by the pick-and-place equipment T (as schematically indicated by the arrow pointing upward), the semiconductor die 14 returns to the “crying” warped/bent shape.

FIG. 4 is a plan view illustrative of the assembly resulting from the processing steps illustrated in FIGS. 3A to 3C.

As illustrated, the die-attach material DA is drawn/sucked in in response to the semiconductor die 14 returning to its “crying” warped shape; this fact is schematically indicated by the arrows at the central portion of the semiconductor die 14 (the portion that rises when the semiconductor die 14 returns to a “crying” warped shape) that point inwardly of the semiconductor die 14.

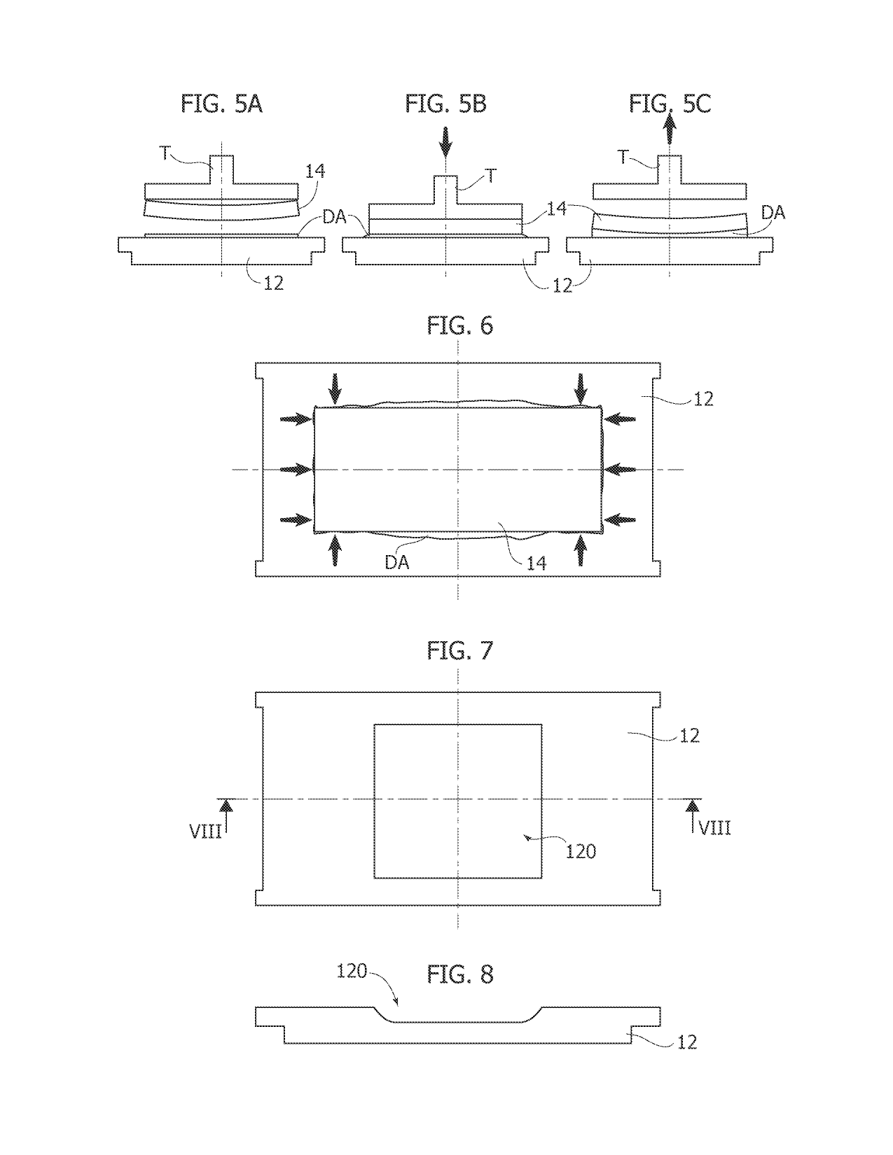

Similarly, FIGS. 5A to 5C are illustrative of a semiconductor die 14 having a “smiling” warpage being arranged on a substrate 12 via die-attach material DA provided on the substrate 12, wherein:

FIG. 5A – a semiconductor die 14 having a “smiling” warped shape is picked and arranged (via pick-and-place equipment T, for instance) over a substrate 12 having die-attach material DA provided at the mounting surface thereof,

FIG. 5B – the semiconductor die 14 is arranged with the die-attachment (back) surface thereof in contact with the die-attach material DA, with mechanical pressure (schematically indicated with an arrow pointing downward in the figure) applied thereto that causes the semiconductor die 14 to flatten and to contact the die-attach material DA, and

FIG. 5C – the semiconductor die 14 is released by the pick-and-place equipment T (as schematically indicated by the arrow pointing upward) and returns to the “smiling” warped/bent shape.

FIG. 6 is a plan view illustrative of an assembly resulting from the processing steps illustrated in FIGS. 5A to 5C.

Also in the case illustrate in FIG. 6, the die-attach material DA is drawn/sucked in in response to the semiconductor die 14 returning to its “smiling” warped shape; this fact is schematically indicated by the arrows at the side portions of the semiconductor die 14 (the portions that rise when the semiconductor die 14 returns to a “smiling” warped shape) that point inwardly of the semiconductor die 14.

The die-attach DA drawn in in response to the semiconductor die 14 returning to a warped shape may cause air (air bubbles, for instance) to enter the die-attach material DA and to get trapped therein, thus forming voids in the die-attach material DA.

Such voids (not illustrated in the figures for simplicity) may negatively affect reliability of the die to die-attach joint, possibly causing detachment of the semiconductor die 14 from the die-attach material DA (and, consequently, causing failure or rejection of the device).

Voids in the die-attach material have been observed to negatively affect the integrity of the semiconductor die 14 when electrically conductive ribbons are provided between the semiconductor die 14 and the substrate 12 to provide electrical coupling therebetween. In fact, ribbons may be used to provide electrical coupling when relatively high intensity currents are transferred between the semiconductor die 14 (a power die, for instance) and the substrate 12. As known to those skilled in the art, ribbons are provided in a bridge-like arrangement, with the end portions thereof welded/bonded via ultrasonic welding to the semiconductor die 14 and to the substrate 12. Ultrasonic welding involve applying a relatively high pressure on the (top) surface of the end portions of the ribbon and, consequently, on the top surface of the semiconductor die 14. It has been observed that the semiconductor die 14 is more likely to break at regions having voids formed in the die-attach material DA below the die 14 when a ribbon is (ultrasonically) welded thereon.

Solutions according to the present description involve mounting a semiconductor die on a substrate having at least one recess formed in a surface thereof.

In solutions as described herein, pillar-like formations may be provided at a surface of a semiconductor die configured to contact die-attach material provided at a surface of a substrate.

In solutions as described herein, the semiconductor die having at a surface the pillar-like formations is arranged on a substrate having one or more recesses formed at the surface thereof, with the pillar-like formations housed in the recess.

In solutions as described herein, the one or more recesses in the surface of the substrate may be at least partially filled with die-attach material.

In solutions as described herein, the pillar-like formations at the surface of the semiconductor die are dipped into the die-attach material partially filling the one or more recesses in the surface of the substrate. Interlocking between the pillar-like formations and the die-attach material counters delamination of the semiconductor die from the die-attach material.

Solutions as described herein may advantageously be applied to semiconductor die having a warped or deformed shape.

FIGS. 7 and 8 are respectively a plan view and a cross-sectional view (along line VIII-VIII of FIG. 7) illustrative of a mounting substrate 12 (a die pad in a leadframe, for instance) according to embodiments of the present description.

As discussed in the following, a mounting substrate 12 as described with reference to FIGS. 7 and 8 may advantageously be used as substrate for semiconductor dice having 14 a “crying” warped shape.

As illustrated, the (mounting) substrate 12 may be formed with a recessed portion or cavity 120 located at a central region of the die mounting surface (that is, the surface of the substrate 12 configured to have a semiconductor die 14 arranged thereon) of the substrate 12.

The recessed portion or recess 120 may be formed during the manufacturing process of the substrate 12 via per se conventional processing steps. In embodiments where the substrate 12 comprises a die pad in a leadframe the recessed portion 120 may be formed via stamping, etching or laser ablation of a conventional leadframe having a (substantially) flat die mounting surface.

The semiconductor die 14 may be provided with pillars or pillar-like formations provided at the die-attachment surface, wherein the semiconductor die 14 is configured to be arranged with the pillars housed in the recessed portion 120 of the substrate 12.

In one or more embodiments, die-attach material DA is provided at a mounting region of a surface of a substrate 12 as illustrated in FIGS. 7 and 8. The mounting region of the surface of the substrate 12 is the region having (substantially) the same size and shape of the semiconductor die 14 that is configured to be mounted on the substrate 12.

As discussed in the following, the recess 120 has a first portion “overlapping” with the die mounting region and that is configured to receive die-attach material DA.

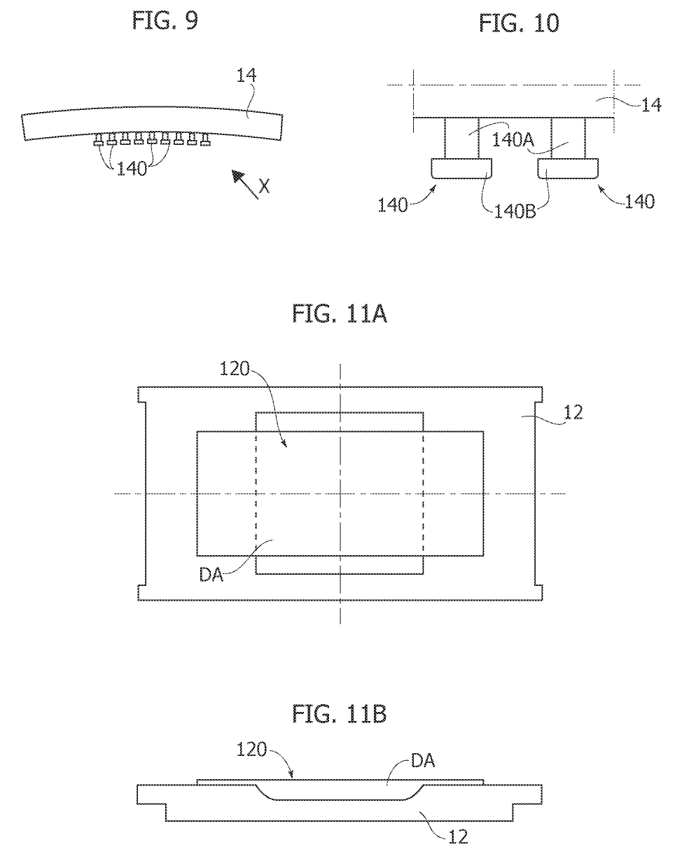

FIGS. 9 and 10 are cross-sectional views (wherein FIG. 10 is an enlarged view of the portion of FIG. 9 indicated by the arrow X) illustrative of a semiconductor die 14 according to embodiments of the present description.

As illustrated in FIG. 9, the semiconductor die 14 has a “crying” warped shape, wherein the die-attachment surface of the semiconductor die 14 has a concave shape, with the edges of the semiconductor die 14 bending downward.

By concave surface is meant a die-attachment surface that is hollowed out or rounded inward of the die so that, when observed from outside the die, the die-attachment surface is essentially cup-shaped or scoop-shaped. On the contrary, by convex surface is meant a die-attachment surface that is curved or rounded outward of the die so that, when observed from outside the die, the die-attachment surface is essentially dome-shaped or bulged/bulging.

As illustrated in FIGS. 9 and 10, pillar-like formations 140 may be provided at the die-attachment surface of the semiconductor die 14, at a central region of the die-attachment surface.

Such pillar-like formations 140 may be formed by growing electrically conductive material (a metallic material such as copper, for instance) via techniques similar to those used for forming pillars/bumps in flip-chip semiconductor dice, for instance.

Advantageously, pillar-like formations 140 may be formed via additive manufacturing techniques such as laser induced forward transfer (LIFT).

The acronym LIFT denotes a deposition process where material from a donor tape or sheet is transferred to an acceptor substrate (here, the LDS material) facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

Electrically insulating pillar-like formations may be formed via LIFT or any other additive manufacturing technique.

With reference to FIG. 10, the pillar-like formations 140 may be formed as “T”-shaped (or mushroom-shaped) pillar-like formations, that is, as columns 140A having a flattened distal end 140B.

It is noted that the pillar-like formations 140 may be formed with other (possibly more complicated) shapes that what is illustrated in the figures by way of example.

As discussed in the following, the pillar-like formations 140 are configured to be “dipped” in the die-attach material DA provided at the surface of the substrate 12. Die-attach material held between the pillar-like formations 140 counters formation of voids in the die-attach material DA. A flattened distal portion 140B of the pillar-like formations 140 (that is, T-shaped or mushroom-shaped pillar-like formations) has been observed to be advantageously effective in “trapping” the die-attach material DA between adjacent pillar-like formations 140 thus countering detachment of the die-attachment of the semiconductor die 14 from the die-attach material DA.

FIGS. 11A to 13A and 11B to 13B are sequences of plan views and cross-sectional views, respectively, illustrative of processing steps according to embodiments of the present description wherein a semiconductor die 14 having pillar-like formations 140 at the die-attachment surface is mounted at a substrate 12 having a recess 120 (as illustrated in FIGS. 7 and 8).

It is noted that while the figures illustrate a semiconductor die provided with pillar-like formations 140 provided at the die-attachment surface thereof, such pillar-like formations 140 are optional features.

As illustrated in FIGS. 11A and 11B, die-attach material DA is provided at the (die-mounting) surface of the substrate 12. Die-attach material DA is provided also at the recess 120 formed in the die-attachment surface of the substrate 12. As illustrated in FIG. 11A, the die-attach material DA may partially fill the recess 120.

In other words, die attach material DA is provided over the whole mounting region of the substrate 12 (that is, the region of the surface that is configured to have the semiconductor die 14 mounted thereon); the (at least one) recess 120 comprises a first portion lying within (or “overlapping” with) the mounting region that receives die-attach material DA.

The recess 120 comprises second portions that extend out of the mounting region. As illustrated in FIG. 11A in the exemplary case of a mounting region having a rectangular shape (that is, the region of the surface of the substrate 12 having die-attach material provided thereon) the second portions of the recess 120 lie adjacent to opposite sides of the mounting region.

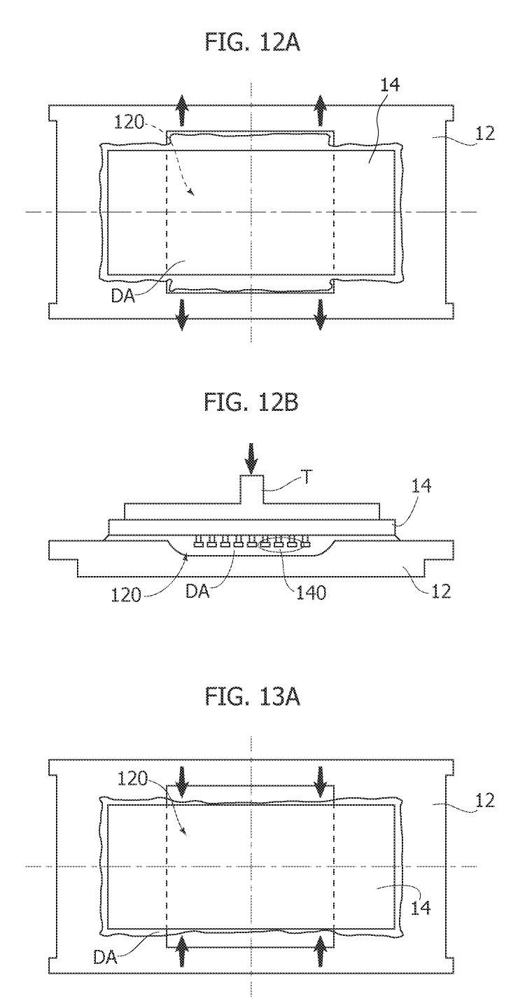

With reference to FIGS. 12A and 12B, a semiconductor die 14 (for instance, a semiconductor die 14 having a concave die-attachment surface) is arranged at the substrate 12 (via pick-and-place equipment T, for instance) with the die-attachment surface in contact with the die-attach material DA provided at the die-mounting surface of the substrate 12.

As schematically indicated by the downward arrow in FIG. 12B, mechanical pressure may be applied onto the semiconductor die 14 in order to facilitate the die-attachment surface (possibly having a concave shape, for instance) to adhere to or to contact the die-attach material DA.

As already mentioned, in applications where the semiconductor die 14 has a warped/deformed shape, the semiconductor die 14 may flatten in response to the mechanical pressure applied thereon.

As illustrated in FIG. 12A, the die-attach material at the die-mounting surface is compressed in response to the semiconductor die 14 being arranged in contact therewith; the die-attach material DA may be squeezed and fill the recess 120 in the die-mounting surface of the substrate 12 (partially filled before arranging the semiconductor die 14).

That is, arranging a semiconductor die 14 onto the die-attach material DA provided at the mounting region causes die-attach material DA to ooze out of the portion of the recess 120 lying within the mounting region, towards the second portions of the recess 120. As illustrated a mass of die-attach material accumulates at the second regions; that mass of die-attach material DA acts as a barrier that counters infiltration of air into the die-attach material at the first region of the recess 120 (that is, the region of the recess 120 beneath the semiconductor die 14).

With reference to FIG. 12B, the pillar-like formations 140 (optionally provided) at the die-attachment surface of the semiconductor die 14 are dipped in the die-attach material DA provided at the recess 120, with the die-attach material DA getting trapped between adjacent pillar-like formations 140. Such mechanical interlocking between the pillar-like formations 140 and the die-attach material DA has been observed to improve adhesion of the semiconductor die 14 to the die-attach material DA, advantageously reducing the risk of delamination/detachment of the semiconductor die 14 from the die-attach material DA.

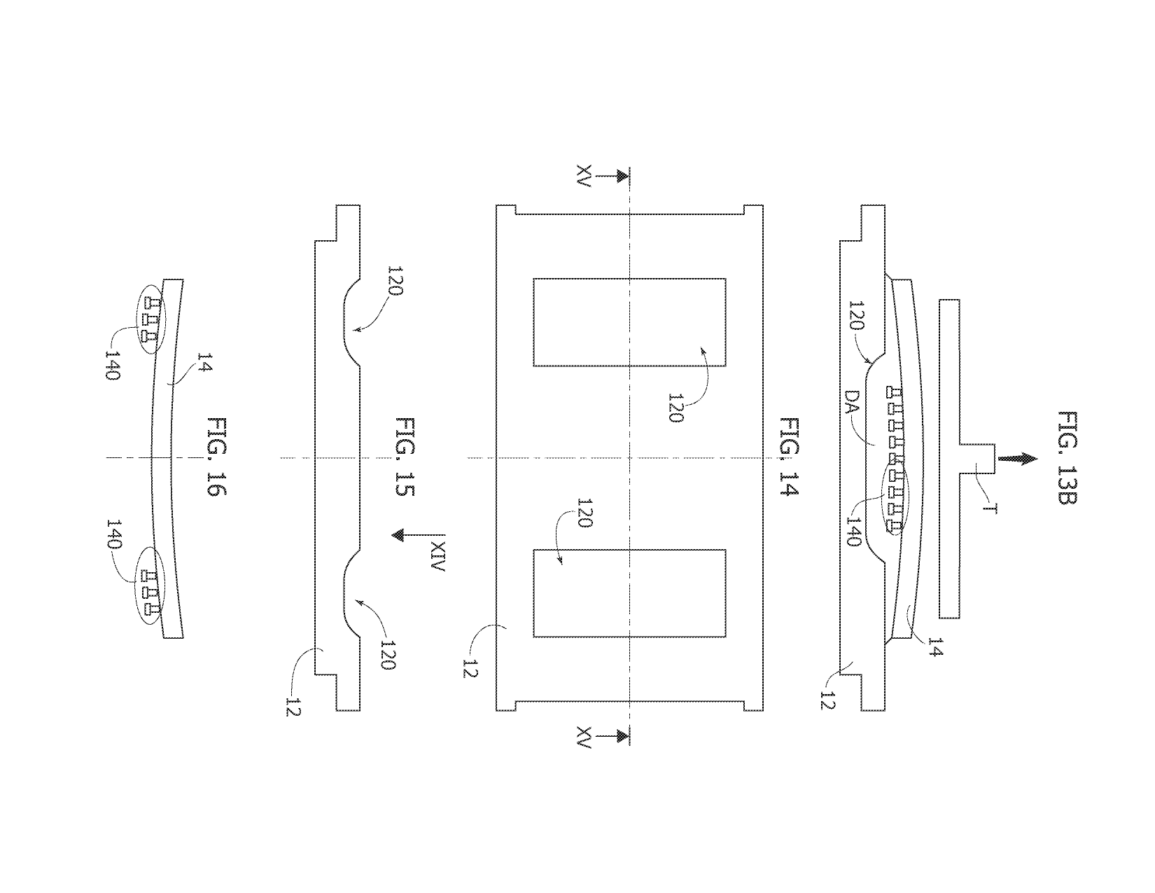

According to an advantageous aspect of the present description, pillar-like formations 140 counter formation of voids in the die-attach material DA when the semiconductor die has warped shape. This fact is illustrated in FIGS. 13A and 13B, wherein the semiconductor die 14 returns to a “crying” warped shape (that is, with a concave die-attachment/back surface) when the semiconductor die 14 is released by the pick-and-place equipment T. Capillary forces hold the die-attach material DA between adjacent pillar-like formations 140 (and in contact with the die-attachment surface of the semiconductor die 14) countering air bubbles to enter in the die-attach material when the semiconductor die 14 returns to its warped shape, thus reducing the risk of forming voids in the die-attachment material DA.

With reference to FIG. 13A, the die-attach material DA is drawn in in response to the semiconductor die 14 returning to its “crying” warped shape (as schematically indicated by the arrows at the central portion of the semiconductor die 14). The die-attach material accumulated at the second portions of the recess 120 may also be (partially) drawn in, countering the entry of air in the die-attach material DA at the mounting region of the substrate 12 (at the first portion of the recess 120 beneath the semiconductor die 14), thus countering formations of voids therein.

It is noted that in embodiments wherein the die-attachment surface of the semiconductor die is provided with pillar-like formations 140 (as exemplified in the figures) formation of voids is further countered in response to the die-attach material DA adhering to the die-attachment surface of the semiconductor die 14 facilitated by the pillar-like formations 140.

FIGS. 14 and 15 are respectively a plan view and a cross-sectional view (along line XV-XV of FIG. 14) illustrative of a substrate 12 according to further embodiments of the present description.

A mounting substrate 12 as illustrated in FIGS. 14 and 15 may advantageously be used as a substrate 12 for a semiconductor die 14 having a “smiling” warped shape (that is, a convex die-attachment surface), for instance.

As illustrated, two (or more) recesses or cavities 120 may be formed in the die-mounting surface of a substrate 12. Similarly to what has been described previously, the two or more recesses 120 are configured to have die-attach material DA provided therein. More in detail, the two recesses 120 have a first portion that lies within (or overlaps with) the mounting region of the surface of the substrate 12 (that is, the region configured to have the semiconductor die 14 mounted thereon) wherein die-attach material DA is provided. Each recess 120 comprises also second portions adjacent to the mounting region. The second portions of the recesses 120 may be left exempt of die-attach material DA when the die-attach material DA is provided at the mounting region.

A semiconductor die 14, possibly provided with pillar-like formations 140 at the die-attachment surface thereof, is thus attached at the die-mounting surface of the substrate 12 (with the die-attachment surface in contact with the die-attach material DA).

Similarly to what has been discussed previously, arranging the semiconductor die 14 onto the die-attach material DA provided at the mounting region causes die-attach material DA to ooze out of the first portion of the recesses 120 and to accumulate at the second portions of the recesses 120. A mass of die-attach material accumulates at the second portions of the recesses 120 and acts as a barrier that counters infiltration of air into the die-attach material at the first portion of the recesses 120 (that is, the region of the recess 120 beneath the semiconductor die 14).

In embodiments where the semiconductor die 14 is provided with pillar-like formations 140 at a surface thereof, the pillar-like formations 140 are dipped in the die-attach material DA provided at the first region of the recesses 120.

FIG. 16 is a cross-sectional view illustrative of a semiconductor die 14 having pillar-like formations 140 at the die-attachment surface thereof, configured to be mounted on a substrate 12 as illustrated in FIGS. 14 and 15.

As illustrated, the semiconductor die 14 may have a “smiling” warped shape (that is, a convex die-attachment surface) to which solutions as described herein may advantageously be applied.

Similarly to what has been described with reference to FIGS. 11A to 13A and 11B to 13B, die-attach material DA is provided at the die-mounting surface of the substrate 12; die-attach material DA is provided also at the first portion of the recesses 120 formed in the die-attachment surface of the substrate 12.

Subsequently, a semiconductor die 14 (for instance, a semiconductor die 14 having a convex die-attachment surface) is arranged at the substrate 12 (via pick-and-place equipment T, for instance) with the die-attachment surface in contact with the die-attach material DA provided at the die-mounting surface of the substrate 12 (possibly applying a mechanical pressure onto the semiconductor die 14 in order to facilitate the die-attachment surface thereof to adhere to the die-attach material DA).

The pillar-like formations 140 possibly provided at the die-attachment surface of the semiconductor die 14 are dipped in the die-attach material DA provided at the recesses 120 promoting mechanical interlocking between the pillar-like formations 140 and the die-attach material DA. As illustrated in FIG. 16, the pillar-like formations 140 may be provided as two sets of pillar-like formations 140 at corresponding distal portions of the semiconductor die 14.

As mentioned previously, such mechanical interlocking has been observed to improve adhesion of the semiconductor die 14 to the die-attach material DA, advantageously reducing the risk of delamination/detachment of the semiconductor die 14 from the die-attach material DA.

A semiconductor die 14 having a “smiling” warped shape as illustrated in FIG. 16, may return to its deformed shape (that is, with a convex die-attachment/back surface) when the semiconductor die 14 is released by the pick-and-place equipment T. Capillary effect/forces hold or “trap” the die-attach material DA between adjacent pillar-like formations 140 countering air bubbles to enter in the die-attach material when the semiconductor die 14 returns to its warped shape, thus reducing the risk of forming voids in the die-attachment material DA.

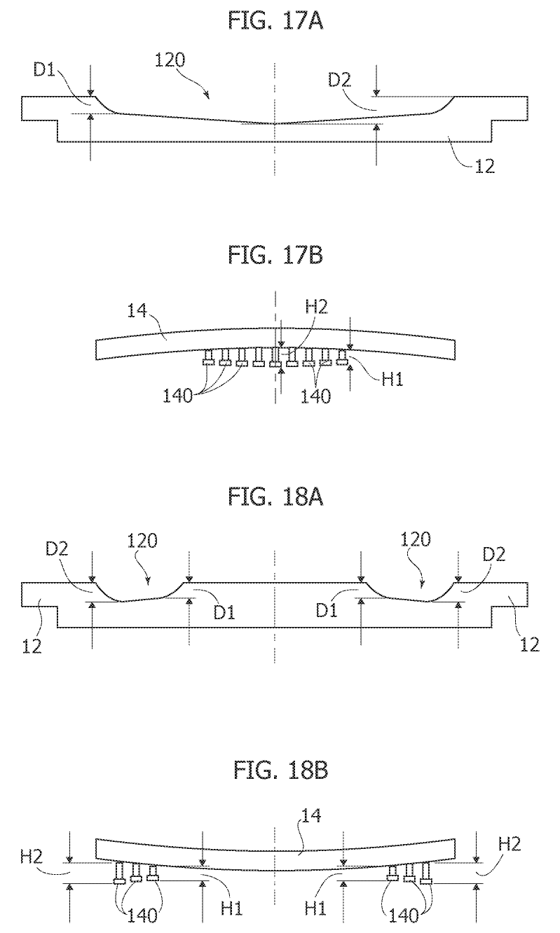

FIGS. 17A, 17B and 18A and 18B are illustrative of further embodiments of the present description. Solutions as described with reference to these figures may advantageously be applied to mounting of semiconductor dice 14 having a warped shape.

With reference to FIGS. 17A and 18A the one or more recesses 120 formed in the die-mounting surface of the substrate 12 may have a varying depth.

With reference to FIG. 17A, the recess 120 may be deeper at a central region thereof (having a maximum depth D2) and shallower at distal regions thereof (with a minimum depth D1).

Correspondingly, as illustrated in FIG. 17B, a semiconductor die 14 (possibly having a concave die-attachment surface, as illustrated in FIG. 17B) may have pillar-like formations 140 provided at the die-attachment surface thereof with a varying height. As illustrated, pillar-like formations 140 may have a maximum height H2 at a central region of the semiconductor die 14 and a height that decreases towards the periphery of the semiconductor die 14 (down to a minimum height H1 of the pillar-like formation 140).

Similarly, with reference to FIG. 18A, the recesses 120 may be deeper at distal regions thereof (having a maximum depth D2) and shallower at proximal regions thereof (with a minimum depth D1).

Correspondingly, as illustrated in FIG. 18B, a semiconductor die 14 (possibly having a convex die-attachment surface, as illustrated in FIG. 18B) may have pillar-like formations 140 provided at the die-attachment surface thereof with a varying height. As illustrated, pillar-like formations 140 may have a maximum height H2 at distal regions of the semiconductor die 14, and a height that decreases towards the center of the semiconductor die 14 (down to a minimum height H1 of the pillar-like formation 140).

Said otherwise, in embodiments as described with reference to FIGS. 17A, 17B, 18A and 18B, the at least one recess 120 in the surface of the substrate 12 has at least one first recess depth D1 and at least one second recess depth D2, the second recess depth D2 being higher than the first recess depth D1. The pillar-like formations 140 at the die-attachment of the semiconductor die 14 may include at least one first set of shorter pillar-like formations 140 configured to be housed at the least one first recess depth D1 in the at least one recess 120 in the surface of the substrate 12 and at least one second set of longer pillar-like formations 140 configured to be housed at the least one second recess depth D2 in the at least one recess 120 in the surface of the substrate 12.

In summary, described herein is a substrate 12 including a surface having a mounting region configured to have a semiconductor die 14 arranged thereon with a die-attachment surface of the semiconductor die 14 in contact with die-attach material DA provided at the mounting region of the surface of the substrate 12.

The surface of the substrate 12 has at least one recess 120 formed therein, the at least one recess 120 including: a first portion lying within the mounting region and configured to receive the die-attach material DA provided therein; and second portions lying adjacent said mounting region, wherein the second portions of at least one recess 120 are configured to provide accumulation spaces for die-attach material DA oozing out of said first portion of at least one recess 120 in response to the semiconductor die 14 being arranged onto said die-attach material DA provided at the mounting region.

In solutions as described herein, a semiconductor die 14 is thus arranged with a die-attachment surface thereof in contact with die-attach material DA provided at a mounting region of a (die-mounting) surface of a substrate 12 (a die pad in a leadframe, for instance). Die-attach material DA is provided at a first portion of at least one recess 120 formed in the surface of the substrate 12. The first portion of the at least one recess 120 lies within the mounting region and the at least one recess 120 comprises second portions lying adjacent the mounting region. The second portions of at least one recess 120 facilitate accumulation of die-attach material DA oozing out of the first portion of at least one recess 120 in response to the semiconductor die 14 being arranged onto the die-attach material DA provided at the mounting region.

Mechanical pressure may be applied onto the semiconductor die 14 arranged onto the die-attach material DA to facilitate accumulation of die-attach material DA at the second portions of the at least one recess 120.

In one or more embodiments, the semiconductor die 14 has a warped shape with a concave die-attachment surface and the substrate 12 has the at least one recess 120 at a central region of the mounting region.

In one or more embodiments, the semiconductor die 14 has a warped shape with a convex die-attachment surface, and the substrate 12 has at least two recesses 120 at corresponding distal regions of the mounting region.

In one or more embodiments, the semiconductor die 14 has at the die-attachment surface pillar-like formations 140 (formed via LIFT, for instance) configured to be housed in the at least one recess 120 in the surface of the substrate 12. The die-attach material DA provided at the first portion of the at least one recess 120 penetrates between adjacent pillar-like formations 140 of the pillar-like formations 140 countering detachment of the die-attachment surface of the semiconductor die 14 from the die-attach material DA.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
arranging a semiconductor die having a die-attachment surface in contact with die-attach material provided at a mounting region of a surface of a substrate;
wherein the die-attach material is provided at a first portion of at least one recess formed in the surface of the substrate;
wherein the first portion of the at least one recess lies within said mounting region and the at least one recess comprises second portions lying adjacent said mounting region;
wherein the second portions of the at least one recess facilitate accumulation of die-attach material oozing out of said first portion of at least one recess in response to the semiconductor die being arranged onto said die-attach material provided at the mounting region.

2. The method of claim 1, wherein the mounting region has a substantially rectangular shape and the second portions of the at least one recess are adjacent to opposite sides of said mounting region and have a substantially rectangular shape.

3. The method of claim 1, further comprising applying mechanical pressure onto the semiconductor die to facilitate accumulation of die-attach material at said second portions of the at least one recess.

4. The method of claim 1, wherein the semiconductor die has a warped shape with a concave die-attachment surface and the substrate has the at least one recess at a central region of the mounting region.

5. The method of claim 1, wherein the semiconductor die has a warped shape with a convex die-attachment surface and the substrate has at least two recesses at corresponding distal regions of the mounting region.

6. The method of claim 1, wherein the semiconductor die has pillar-like formations at the die-attachment surface, said pillar-like formations configured to be housed in the at least one recess in the surface of the substrate, wherein said die-attach material provided at the first portion of the at least one recess penetrates between adjacent pillar-like formations of said pillar-like formations countering detachment of the die-attachment surface of the semiconductor die from the die-attach material.

7. The method of claim 6, wherein:
the at least one recess in the surface of the substrate has at least one first recess depth and at least one second recess depth, the second recess depth being higher than the first recess depth; and
the pillar-like formations at the die-attachment surface of the semiconductor die include at least one first set of shorter pillar-like formations configured to be housed at the least one first recess depth in the at least one recess in the surface of the substrate and at least one second set of longer pillar-like formations configured to be housed at the least one second recess depth in the at least one recess in the surface of the substrate.

8. The method of claim 6, comprising providing said pillar-like formations at the die-attachment surface of the semiconductor die as T-shaped pillar-like formations.

9. A substrate, wherein the substrate includes a surface having a mounting region configured to have a semiconductor die arranged thereon with a die-attachment surface of the semiconductor die in contact with die-attach material provided at the mounting region of the surface of the substrate;
wherein the surface of the substrate has at least one recess formed therein, the at least one recess including:
a first portion lying within said mounting region and configured to receive the die-attach material provided therein; and
second portions lying adjacent said mounting region, wherein the second portions of the at least one recess are configured to provide accumulation spaces for die-attach material oozing out of said first portion of at least one recess in response to the semiconductor die being arranged onto said die-attach material provided at the mounting region.

10. A device, comprising:
a semiconductor die arranged with a die-attachment surface in contact with die-attach material provided at a mounting region of a surface of a substrate;
wherein die-attach material is provided at a first portion of at least one recess formed in the surface of the substrate;
wherein the first portion of the at least one recess lies within said mounting region and the at least one recess comprises second portions lying adjacent said mounting region;
wherein the second portions of at least one recess provide accumulation spaces for die-attach material oozing out of said first portion of at least one recess in response to the semiconductor die being arranged onto said die-attach material provided at the mounting region.

11. The device of claim 10, wherein the mounting region has a substantially rectangular shape and the at least one recess comprises second portions adjacent to opposite sides of said mounting region having a substantially rectangular shape.

12. The device of claim 10, wherein the semiconductor die has a warped shape with a concave die-attachment surface, and the substrate has the at least one recess at a central region of the mounting region.

13. The device of claim 10, wherein the semiconductor die has a warped shape with a convex die-attachment surface, and the substrate has at least two recesses at corresponding distal regions of the mounting region.

14. The device of claim 10, wherein the semiconductor die has at the die-attachment surface pillar-like formations configured to be housed in the at least one recess in the surface of the substrate, wherein said die-attach material penetrates between adjacent pillar-like formations of said pillar-like formations countering detachment of the die-attachment surface of the semiconductor die from the die-attach material.

15. The device of claim 14, wherein:
the at least one recess in the surface of the substrate has at least one first recess depth and at least one second recess depth, the second recess depth being higher than the first recess depth, and
the pillar-like formations at the die-attachment of the semiconductor die include at least one first set of shorter pillar-like formations configured to be housed at the least one first recess depth in the at least one recess in the surface of the substrate and at least one second set of longer pillar-like formations configured to be housed at the least one second recess depth in the at least one recess in the surface of the substrate.

16. The device of claim 14, wherein said pillar-like formations provided at the die-attachment surface of the semiconductor die are T-shaped pillar-like formations.
